(19) United States
(12) Patent Application Publication
(10) Pub. No.: US 2003/0013045 A1
(43) Pub. Date: Jan. 16, 2003

(54) Method for producing bond pads on a printed circuit

(76) Inventors: Myriam Oudart, Villebon Sur Yvette (FR); Francois Bernard, Les Ulis (FR); Marie-Jose Molino, Fontenay Aux Roses (FR); Bruno Reig, Sucy En Brie (FR)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/204,561

(22) PCT Filed: Dec. 20, 2001
(86) PCT No.: PCT/FR01/04117

(30) Foreign Application Priority Data
Dec. 28, 2000 (FR) 00/17230

(51) Int. Cl. G03C 5/00

(52) U.S. Cl. 430/313; 430/315; 430/317; 430/318; 430/330; 438/597; 438/613

(57) ABSTRACT

This production process is designed to produce a chromium layer (4) making it possible as it were for the material of the connection bump (8) to remain in a region perfectly bounded by the chromium layer (4).

Applications: Connection bumps for electronic components.

The invention relates to a process for producing connection bumps and especially connection bumps on a printed circuit or an integrated circuit.

The invention is especially applicable in the production of very small connection bumps, for example having a diameter of 200 μm, or even less, and a thickness of 100 microns, again or even less. In addition, these connection bumps must be relatively homogeneous in constitution with few defects, this being so over the entire circuit.

Moreover, in the known techniques the dimensions of a connection bump on the surface of the circuit are commonly bounded by a layer of insulating material. This layer of insulation has a not insignificant thickness, which means that the height of the connection bump is either relatively great or very slightly greater than the thickness of the layer of insulation. In addition, the geometry of the bump is of poor quality. The invention aims to remedy these drawbacks.

The invention therefore relates to a process for producing connection bumps on a circuit having at least one conducting track, characterized in that it comprises the following steps:

a) deposition of a thin copper layer and a chromium layer on the surface of the entire circuit;

b) deposition of a layer of resin and removal of this resin at the places where the bumps are to be produced and also at the places where there is no conducting track;

c) removal of the chromium layer at the places left free by the resin;

d) removal of the resin;

e) deposition of a photosensitive film and formation of apertures in this film at the places where it is desired to produce connection bumps;

f) deposition of a connection material in said apertures;

g) removal of the photosensitive film;

h) removal of the copper layer in those places of the circuit which are not covered by the chromium layer or by the connection material; and

i) heating of the assembly so as to reach the melting point of the connection material.

The various objects and features of the invention will now be described with reference to the description which follows, given as an example, and the appended figures which show:

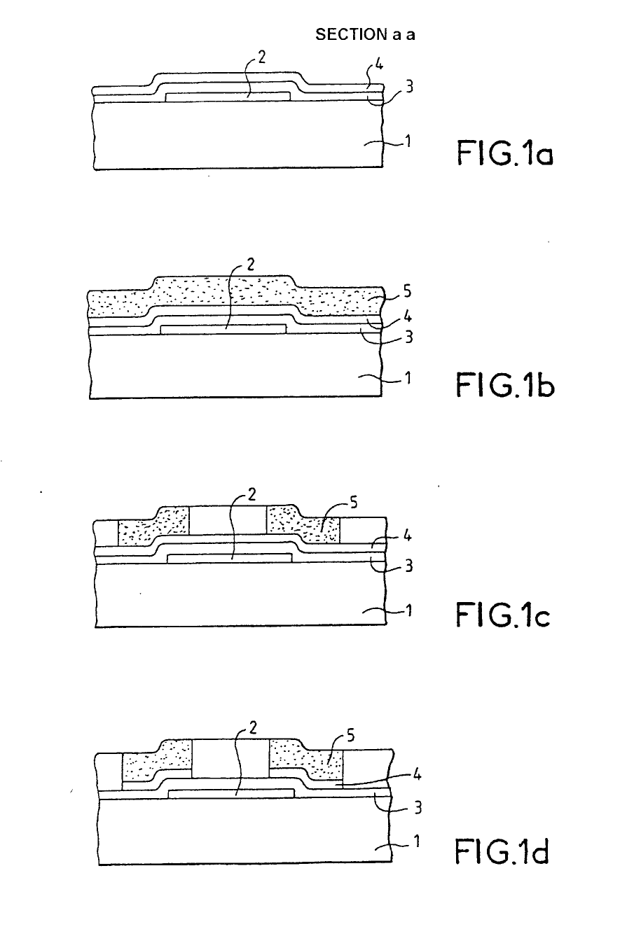

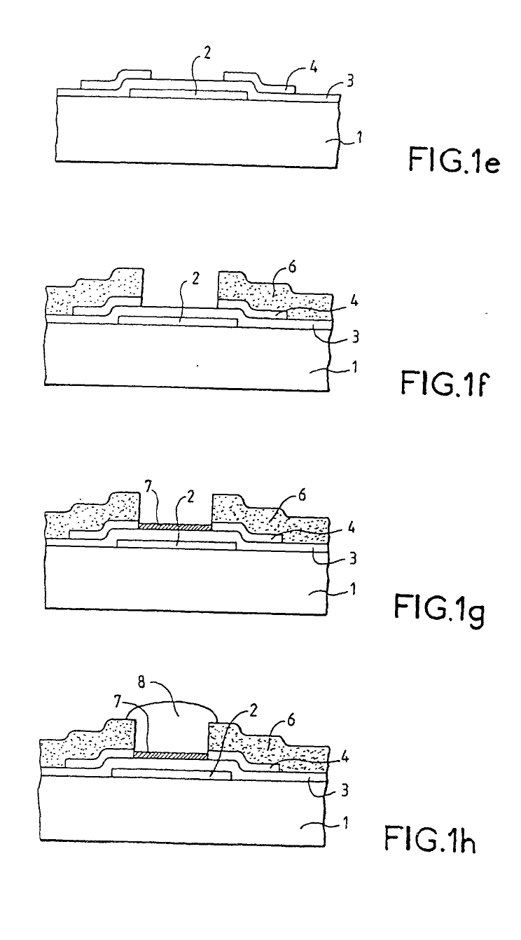

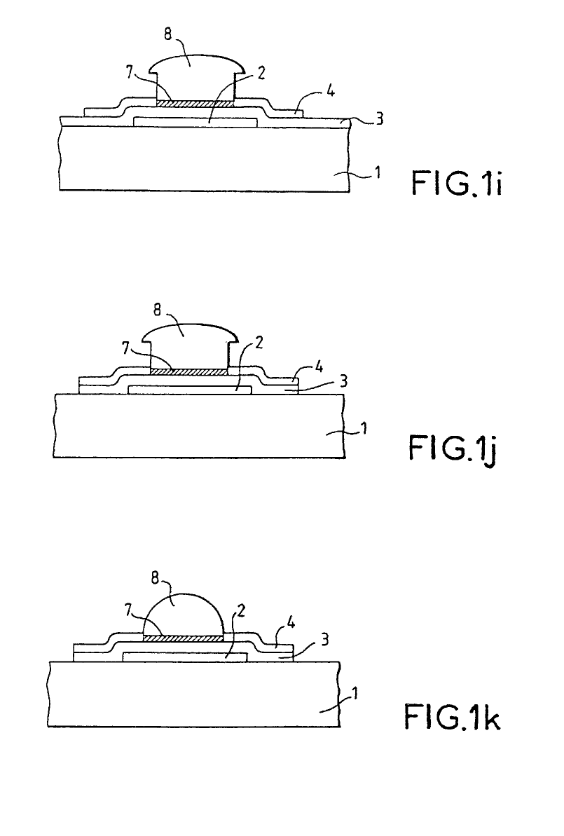

FIGS. 1a to 1k, an example of a production process according to the invention showing, by sectional views of the device produced, the various steps of the process; and

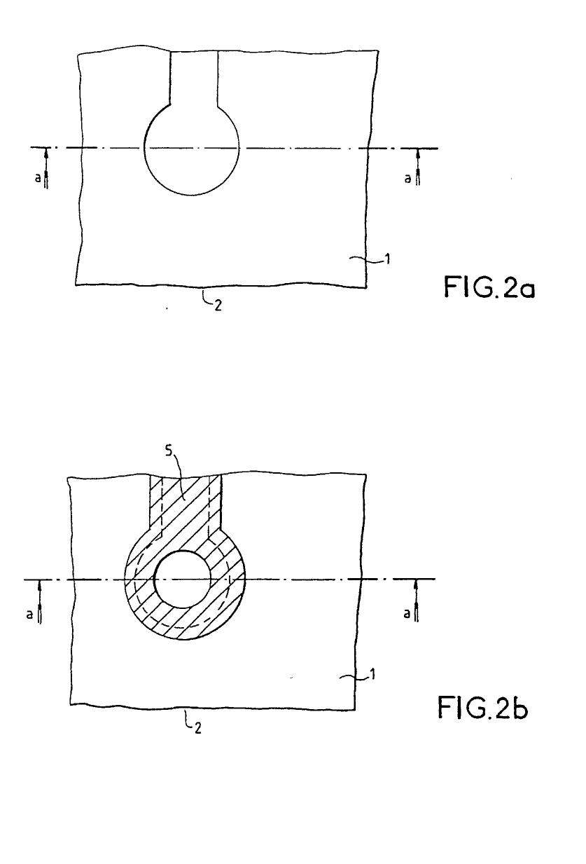

FIGS. 2a and 2b, a device seen from above at various steps of the process according to the invention.

A production process according to the invention will therefore now be described.

During a first step, a thin copper layer 3 and then a thin chromium layer 4 of a few microns or even a few tens of microns are produced on a substrate 1 carrying at least one conducting track or conducting pad 2.

FIG. 2a shows, by way of example, a top view of the device of FIG. 1a. FIG. 2a therefore shows that, as an example, the substrate 1 carries a conductor and an enlarged part corresponding to a connection pad. During a second step, as shown in FIG. 1b, a photosensitive resin 5 is deposited.

During a third step, shown in FIG. 1c, the resin 5 located at the places where the connection bumps are to be produced, and also at the point where there is no conducting track, is removed by any process known in the art. FIG. 2b shows the device at this stage of the process. During a fourth step, as shown in FIG. 1d, the chromium is removed from the regions unprotected by the resin 5 by any process and especially by a chemical etching process. During a fifth step, as shown in FIG. 1e, the resin layer 5 is removed.

During a sixth step (FIG. 1f), a photosensitive film 6 is deposited and produced in this layer of photosensitive material 6 are apertures corresponding to the surface of the connection bumps to be produced.

Next, during a seventh step, an overlay (from 5 to 10 μm in thickness) of copper 7 is produced on the thin copper layer 3 in the apertures thus obtained (FIG. 1g).

Next, during an eighth step shown in FIG. 1h, a conducting material such as tin-lead (SnPb) is deposited, which deposited material will allow a connection bump 8 to be produced.

During a ninth step, the photosensitive film 6 is removed (FIG. 1i).

Next, during a tenth step, the copper is removed from the surface of the circuit in all the regions not protected by the chromium layer 4 and the conducting material 8 (FIG. 1j).

Finally, during an eleventh step, the assembly is heated so that it reaches the melting point of the tin-lead mixture 8 so that the tin-lead mixture assumes the shape of an almost spherical bump, the surface of this bump being clearly bounded by the chromium layer 4 located around the tin-lead mixture.

1. A process for producing connection bumps on a circuit having at least one conducting track, characterized in that it comprises the following steps:
a) deposition of a thin copper layer (3) and a chromium layer (4) on the surface of the entire circuit;
b) deposition of a layer of resin (5) and removal of this resin at the places where the bumps are to be produced and also at the places where there is no conducting track;
c) removal of the chromium layer at the places left free by the resin (5);
d) removal of the resin (5);
e) deposition of a photosensitive film (6) and formation of apertures in this film at the places where it is desired to produce connection bumps;
f) deposition of a connection material (8) in said apertures;
g) removal of the photosensitive film (6);
h) removal of the copper layer in those places of the circuit which are not covered by the chromium layer or by the connection material (8); and
i) heating of the assembly so as to reach the melting point of the connection material.

2. The process as claimed in claim 1, characterized in that the connection material is tin-lead.

3. The process as claimed in claim 1, characterized in that it provides, between steps (d) and (e), a step in which a copper layer (7) is deposited in the apertures produced in the film (6) during step (e).
